(19) United States
(12) Patent Application Publication
(10) Pub. No.: US 2008/0054458 A1
(43) Pub. Date: Mar. 6, 2008

(54) Electronic device and method of manufacturing the same

(76) Inventor: Hiroshi Ozaki, Kanagawa (JP)

Correspondence Address: ROBERT J. DEPKE;LEWIS T. STEADMAN, ROCKEY, DEPKE & LYONS, LLC, SUITE 5450 SEARS TOWER, CHICAGO, IL, 60606-6306, US

(21) Appl. No.: 11/890,671

(22) Filed: Aug. 7, 2007

(30) Foreign Application Priority Data
Aug. 10, 2006 (JP) JP 2006-217640

(51) Int. Cl. H01L 23/488; H01L 21/60

(52) U.S. Cl. 257/737; 438/108; 257/E21.506; 257/E23.023

(57) ABSTRACT

An electronic device includes bump electrodes that are formed of an elemental metal having a low melting point and electrically bond a first component and a second component and protective layers that are formed at least on sides of the bump electrodes and prevent penetration of a substance that deteriorates a characteristic of the bump electrodes.

### CROSS-REFERENCES TO RELATED APPLICATIONS

The present invention contains subject matter related to Japanese Patent Application JP 2006-217640 filed in the Japanese Patent Office on Aug. 10, 2006, the entire contents of which being incorporated herein by reference.

### BACKGROUND OF THE INVENTION

1. Field of the Invention

The present invention relates to an electronic device that has junctions formed by bump electrodes, and, more particularly to an electronic device and a method of manufacturing the same that can prevent deterioration in the bump electrodes and improve reliability of the electronic device.

2. Description of the Related Art

In electronic apparatuses represented by mobile products such as a cellular phone, there are strong demands for an increase in integration, a reduction in size, and an improvement of performance. In order to meet these demands, flip-chip connection for connecting a semiconductor chip to a mounting substrate or another semiconductor chip via bump electrodes is widely adopted. It is necessary to reduce a wiring delay (an RC delay) to realize an increase in speed. When a copper wire having a low electrical resistivity and a low dielectric film (Low-k) having a low dielectric constant (K) are used as interlayer insulating film, fusion bonding performed by using solder bump electrodes having a low melting point is adopted as a low damage packaging technique. In order to secure reliability of electrical connection in a bonded product manufactured by the flip-flop connection against various kinds of stress, in general, an under-fill material is filled in a gap between bonded surfaces.

In a semiconductor device in which a substrate material that has low heat resistance and tends to cause deterioration in characteristics due to heating is used, in order to prevent the deterioration in characteristics caused in a manufacturing process thereof, a low-temperature process is used as long as possible. For example, for electrical connection of substrates, there is a technique for forming indium (In) bump electrodes on semiconductor chips using In as a leadless bump electrode material and flip-chip connecting the semiconductor chips via the In bump electrodes. Since the In bump electrodes are made of low-melting metal, there is an advantage that connection at low temperature is possible. In packaging of semiconductor chips with In bump electrodes in the past, pad electrodes are formed in upper and lower semiconductor chips, Ni layers are formed on the pad electrodes, In bump electrodes are formed on the Ni layers, and the upper and lower semiconductor chips are flip-chip connected to bond the same.

FIGS. 4A and 4B are a sectional view for explaining bonding of substrates via In bump electrodes in the technique in the past.

As shown in FIG. 4A, an upper substrate 10 having In bump electrodes 30 formed on pad electrodes 15 electrically isolated from each other by an insulating layer 25 is electrically connected to a lower substrate 20 via the In bump electrodes 30 by flip-chip connection.

Subsequently, as shown in FIG. 4B, in order to protect the electrical connection between the upper substrate 10 and the lower substrate 20 via the In bump electrodes 30 and secure reliability of a bonded product, an under-fill material 35 is filled in a gap between the upper substrate 10 and the lower substrate 20 as a sealing material and hardened.

As semiconductor devices in which In bump electrodes are used, a hybrid imaging device, a hybrid infrared sensor, and the like described later are reported. As a method of manufacturing the In bump electrode, several methods are reported.

In JP-A-9-82757 entitled “Semiconductor Device and Method of Manufacturing the Semiconductor Device” (paragraphs 0003 to 0005 and FIG. 2) and JP-A-2004-200196 entitled “Flexible Substrate and Semiconductor Device” (paragraphs 0008 and 0009, paragraphs 0013 and 0014, and FIG. 1), there are the following descriptions.

FIGS. 5A and 5B are diagrams for explaining bonding by bump electrodes. FIG. 5A corresponds to FIG. 2 in JP-A-9-82757 and is a diagram for explaining a main part structure of a hybrid imaging element and FIG. 5B corresponds to FIG. 1 in JP-A-2004-200196 and is a sectional view showing a schematic structure of a COF (Chip On Flexible substrate) structure.

As shown in FIG. 5A, in an imaging device 111 disclosed in JP-A-9-82757, a detection element 113 having a large number of photoelectric conversion elements formed thereon is mounted on a circuit element 112 having a signal processing circuit formed thereon. Electrodes of the large number of photoelectric conversion elements formed on a lower surface of the detection element 113 and a large number of electrodes formed on an upper surface of the circuit element 112 are connected by bump electrodes 114 containing indium as a main component. In general, pads 114 are formed in predetermined portions of the circuit element 112 or the detection element 113 by a lift-off method. The circuit element 112 and the detection element 113 are pressed with the bump electrodes 114 sandwiched between the elements and are heated to a melting temperature of the bump electrodes 114 to be connected.

A semiconductor device disclosed in JP-A-2004-200196 includes an IC chip including bump electrodes having a surface film of Cu, Ni, Al, Ti, Au, or Pd formed thereon and a flexible substrate on which lead terminals subjected to plating of Au, Cu, Ni, or Pd or lead terminals formed of only a lead material are provided and the bump electrodes are compress-bonded to the lead terminals. Consequently, it is possible to compress-bond the bump electrodes to the lead terminals by using metal other than Au as a surface material of the bump electrodes. Thus, it is possible to realize a reduction in cost of the COF structure.

In FIG. 5B, lead terminals 102 are provided on a flexible substrate 101. The lead terminals 102 includes Cu substrate layers 102a coated with Au plating layers 102b. On the other hand, bump electrodes 104 are provided on an IC chip 103. In the bump electrodes 104, metal plating layers 104b of metal other than Au are applied over metal cores 104a of metal other than Au. Here, as a material of the metal cores 104a, it is possible to use, for example, Cu, Ni, or Pd. As a material of the metal plating or film layers 104b, it is possible to use, for example, Cu, Ni, Al, or Pd.

It is possible to mount the IC chip 103 on the flexible substrate 101 by compress-bonding the bump electrodes 104 on the lead terminals 102. Consequently, when the bump electrodes 104 are compress-bonded to the lead terminals 102, it is possible to use metal other than Au as a material of the bump electrodes 104. Thus, it is possible to realize a reduction in cost of the COF structure.

In Nishino et al., FUJITSU, 56, p. 352-357 (2005) entitled “Quantum Well Infrared Photodetector” (“Summary”, “QWIP-FPA and Optical Coupling Structure”, and FIG. 3), there are the following descriptions.

A Quantum Well Infrared Photodetector (QWIP) that absorbs infrared rays between quantization levels in a quantum well formed by a laminated structure of semiconductor having different band gaps is developed using III-V-semiconductor. A large-scale two-dimensional array (QWIP-Focal Plane Array (QWIP-FPT)) obtained by hybridizing the QWIP and an Si signal readout circuit with bump electrodes of indium is realized. A QWIP infrared photodetector used in an actual infrared camera includes a QWIP two-dimensional array in which QWIP elements are arranged in a two-dimensional array shape and an Si signal readout circuit that reads out signals of respective pixels in time series. The QWIP infrared photodetector adopts a hybrid structure in which the respective QWIP elements are bonded to the Si signal readout circuit by bump electrodes (columnar electrodes that connect pixels) of indium (In) in a one to one relation.

### SUMMARY OF THE INVENTION

Indium (In) is softest among solid metals that are stable under the room temperature. In is substantially limitlessly deformed by compression, has a melting point as low as 156.4° C., and does not have phase transformation. Thus, in a semiconductor device that needs to be manufactured in a low-temperature process or a semiconductor device in which stress tends to be caused by a heat cycle and relaxation of this stress is necessary, when a semiconductor chip substrate is bonded to a mounting substrate or another semiconductor chip substrate, In is used as, for example, a material of bump electrodes (projection electrodes) formed on pad electrodes of a semiconductor chip.

Since the In bump electrodes have a low melting point, it is possible to reduce an influence of heat on substrate materials and elements forming the semiconductor device when the substrates are bonded. Further, it is possible to disperse stress applied to junctions. However, when moisture is present, In tends to rust. Concerning reliability of the junctions, it is necessary to take into account humidity resistance against the presence of moisture. In the past, the humidity resistance is not sufficiently taken into account.

As shown in FIG. 4B, after the flip-chip connection via the In bump electrodes, usually, resin of epoxy or the like called under-fill is injected into a gap between the upper and lower substrates and hardened to secure reliability of a bonded product. Compared with solder metal such as Sn, In easily corrodes when In comes into contact with moisture (H₂O). As shown in FIG. 4B, since the under-fill material 35 and the In bump electrodes 30 are directly in contact with each other, the In bump electrodes 30 corrode because of an influence of moisture that permeates into the under-fill material 35 from the outside. Therefore, in a reliability evaluation by a high-temperature high-humidity test (85° C./85% RH) or the like, the In bump electrodes have low reliability in terms of humidity resistance compared with bump electrodes made of other solder metals.

In the semiconductor chip having the In bump electrodes formed thereon, it is conceivable to protect the In bump electrodes by, for example, forming a gold plating layer and coating the In bump electrodes with the gold plating layer in advance. However, when the upper and lower semiconductor chips are bonded, it is necessary to set the temperature of the bonding to be equal to or higher than the melting point of gold of 1063° C. and bring the gold plating layer into a fused state. This does not conform to the purpose of using the In bump electrodes to realize the low-temperature process. Moreover, it is likely that the In bump electrodes are exposed to a high temperature and oxidation of the In bump electrodes worsens.

The semiconductor device in which the In bump electrodes are used is explained above as an example. However, not only in the semiconductor device but also in electronic devices in which first and second components are bonded via bump electrodes, deterioration in characteristics of the bump electrodes such as electrical characteristics (a electrical conductivity, an electrical resistance, etc.), mechanical characteristics (tensile strength, compression strength, etc.) causes deterioration in reliability of the electronic devices in which the bump electrodes are used. This leads to short durable life of the electronic devices. Thus, there is a strong demand for prevention of the deterioration in the characteristics of the bump electrodes.

Therefore, it is desirable to provide an electronic device and a method of manufacturing the same that can prevent deterioration in bump electrodes of an electronic device that has junctions formed by bump electrodes and can improve reliability of the electronic device.

According to an embodiment of the present invention, there is provided an electronic device including bump electrodes that are formed of an elemental metal having a low melting point and electrically bond a first component and a second component and protective layers that are formed at least on sides of the bump electrodes and prevent penetration of a substance that deteriorates a characteristic of the bump electrodes.

According to another embodiment of the present invention, there is provided a method of manufacturing an electronic device including a first step of electrically bonding a first component and a second component using bump electrodes formed of an elemental metal having a low melting point and a second step of forming, at least on sides of the bump electrodes, protective layers that prevent penetration of a substance that deteriorates a characteristic of the bump electrodes.

In the electronic device according to the embodiment of the present invention, the protective layers that prevent penetration of a substance that deteriorates a characteristic of the bump electrode are formed at least on the sides of the bump electrodes. Thus, it is possible to prevent penetration of a substance that deteriorates characteristics (electrical characteristics such as an electrical conductivity and an electrical resistance, mechanical characteristics such as tensile strength and compression strength, etc.), which occurs under an environment in which the electronic device is placed. Therefore, it is possible to prevent the deterioration in the characteristics of the bump electrodes, improve reliability of the electronic device, and realize extension of durable life of the electronic device.

In the method of manufacturing an electronic device according to the embodiment of the present invention, the protective layers that prevent penetration of a substance that deteriorates characteristics of the bump electrodes are formed at least on the sides of the bump electrodes. Thus, penetration of a substance that deteriorates characteristics, which occurs under an environment in which the electronic device is placed, is prevented by the protective layers. The deterioration in the characteristics of the bump electrodes is prevented. Therefore, it is possible to manufacture an electronic device with improved reliability.

In an electronic device according to an embodiment of the present invention, it is preferable that the pad electrodes formed on the first and second components, respectively, are electrically connected by the bump electrodes and the protective layers are formed to prevent the bump electrodes from being exposed to the outside. The protective layers are formed to prevent the surfaces of the bump electrodes, which electrically connect the pad electrodes formed on the first and second components, respectively, from being exposed to the outside. The sides of the bump electrodes are coated with the protective layers. Thus, the protective layers act as moisture penetration preventing layers (layers that do not easily allow water vapor and water to pass) and corrosion preventing layers (corrosion resistant layers) under various environments in which the electronic device is placed, for example, an environment of high humidity and an environment in which corrosive gas tends to be generated. Thus, an elemental metal forming the bump electrodes can keep characteristics inherent in the elemental metal. Therefore, it is possible to improve reliability of the electronic device.

It is preferable that the protective layers are formed on the sides of the bump electrodes. All the sides of the bump electrodes exposed to the outside are coated with the protective layers. The bump electrodes are protected from a substance that deteriorates characteristics of the bump electrodes (hereinafter simply referred to as characteristic deteriorating substance).

It is preferable that a part of the pad electrodes are coated with the protective layers. Since the junctions of the bump electrodes and the pad electrodes are also coated with the protective layers, the junctions are also protected from the characteristic deteriorating substance.

It is preferable that the bump electrodes are formed of elemental indium metal. It is possible to obtain, making use of the characteristics inherent in elemental indium metal, an electronic product that has junctions that has a low melting point, makes the low-temperature process possible, and is excellent in flexibility and stress resistance.

It is preferable that the protective layers are formed of metal having a high melting point. Even when an environmental temperature in which the electronic device is placed rises to be close to a melting point of an elemental metal forming the bump electrodes, since the protective layers do not come into a fused state, the bump electrodes are protected by the protective layers.

It is preferable that an under-fill material is filled in the gap between the first component and the second component. Since the bump electrodes are coated with the protective layers, the under-fill material filled in the gap protects the bump electrodes against an external environment without directly coming into contact with the bump electrodes. In other words, the bump electrodes are doubly protected by the protective layers and the under-fill material. Even if there is a characteristic deteriorating substance (e.g., moisture in the environment) that enters the under-fill material from the outside and approaches the bump electrodes, the characteristic deteriorating substance is intercepted by the protective layers and the bump electrodes are protected against the characteristic deteriorating substance. Thus, it is possible to prevent deterioration in the characteristics due to the characteristic deteriorating substance and it is possible to improve reliability of the electronic device.

It is preferable that the first component is a first semiconductor chip and the second component is a second semiconductor chip or a mounting substrate. It is preferable that the mounting substrate is an interposer substrate or a motherboard substrate. It is possible to improve reliability of the electronic device in which the semiconductor chips and the interposer substrate or the motherboard substrate are used in combination.

It is preferable that the electronic device constitutes a semiconductor device. It is possible to improve reliability of the semiconductor device in which the semiconductor chips are bonded via the bump electrodes and used as components.

In the method of manufacturing an electronic device according to the embodiment of the present invention, it is preferable that the method includes a third step of filling an under-fill material in a gap between the first component and the second component. It is possible to manufacture, by filling the under-fill material in the gap, an electronic device that has the bump electrodes doubly protected by the protective layers and the under-fill material.

It is preferable that, in the second step, plating layers of metal having a high melting point are formed as the protective layers. It is preferable that the plating layers are formed by electroless plating. It is possible to appropriately adjust the thickness of the plating layer according to time in which the plating layers are formed. Exposed portions of pad electrodes electrically connected by the bump electrodes are coated with the plating layers together with exposed sides of the bump electrodes. Junctions of the bump electrodes and the pad electrodes are also coated with the plating. Thus, the junctions are also protected from a characteristic deteriorating substance.

In the embodiments of the present invention, the “low melting point” means a melting point equal to or lower than 200° C. and the “high melting point” means temperature exceeding the melting point of an elemental metal forming the bump electrodes, i.e., a melting point exceeding 200° C. The high melting point is set to hold performance of the protective layers because, if the metal having the high melting point is brought into a fused state by temperature at the time of bonding and the protective layers are broken, the performance of the protective layers is lost. It is preferable that the protective layers are formed of metal that can act as rust resistant layers having rust preventiveness and moisture penetration preventing layers having moisture penetration resistance. The “characteristics of the bump electrodes” means electrical characteristics such as an electrical conductivity and an electrical resistance, mechanical characteristics such as tensile strength and compression strength, and the like of the bump electrodes.

### BRIEF DESCRIPTION OF THE DRAWINGS

FIGS. 1A to 1D are sectional views for explaining a semiconductor device formed by bonding of substrates via In bump electrodes according to an embodiment of the present invention.

FIG. 2 is a flowchart for explaining a procedure of the bonding of the substrates via the In bump electrodes according to the embodiment;

FIG. 3 is a sectional view for explaining an example of dimensions of a junction of the semiconductor device formed by the bonding of the substrates via the In bump electrodes;

FIGS. 4A and 4B are sectional views for explaining bonding of substrates performed by using In bump electrodes in a technique in the past; and

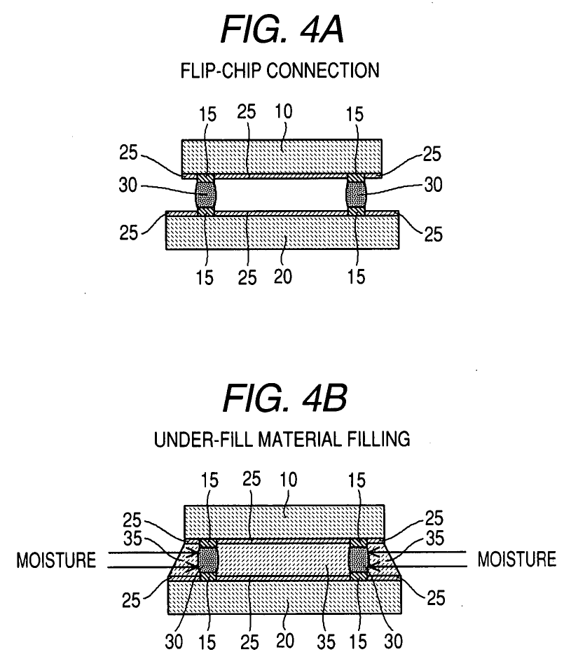

FIGS. 5A and 5B are diagrams for explaining the bonding by the In bump electrodes in the technique in the past.

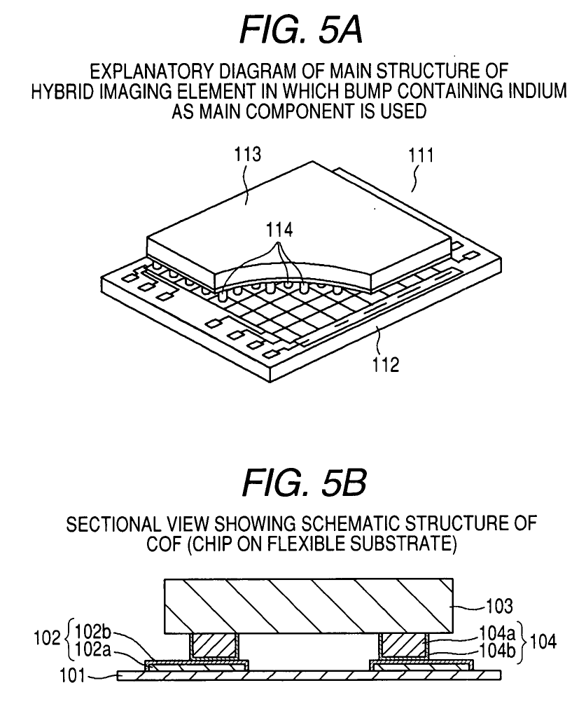

### DESCRIPTION OF THE PREFERRED EMBODIMENTS

An embodiment of the present invention will be hereinafter explained in detail with reference to the drawings. In the following explanations, a semiconductor device in which semiconductor chips are bonded as components via bump electrodes will be explained as an example of an electronic device.

In the semiconductor device according to this embodiment, semiconductor chip substrates having In bump electrodes formed thereon are flip-chip connected. Subsequently, before filling an under-fill material in a gap between the semiconductor chip substrates, the In bump electrodes and pad electrodes (formed by a Cu or Ni layer) having the In bump electrodes formed thereon are covered with metal plating layers of metal other than In, e.g., gold plating layers by electroless Au plating. Then, the under-fill material is filled in the gap and hardened. Thus, it is possible to prevent direct contact of the In bump electrodes and moisture and remarkably improve durable life evaluated by a reliability test such as a high-temperature high-humidity test. Thus, it is possible to improve reliability of the semiconductor device formed by a flip-chip mounting structure having the In bump electrodes.

In this embodiment, it is possible to realize flip-chip mounting performed by using the In bump electrodes that can make use of characteristics that the In bump electrodes are soft and have a low melting point and improve humidity resistance, which is low in the In bump electrodes in the past, to be as high as that of other kinds of leadless solder.

Since the In bump electrodes are soft, cracks are not easily formed by an external force. The In bump electrodes have crack resistance and is excellent in stress resistance. Since the In bump electrodes have the low melting point, flip-chip connection at a low temperature is possible, thermal stress is not easily generated, and the semiconductor chip substrate or the mounting substrate as components to be bonded is not damaged by heat. Therefore, it is possible to manufacture a semiconductor device according to the low-temperature process.

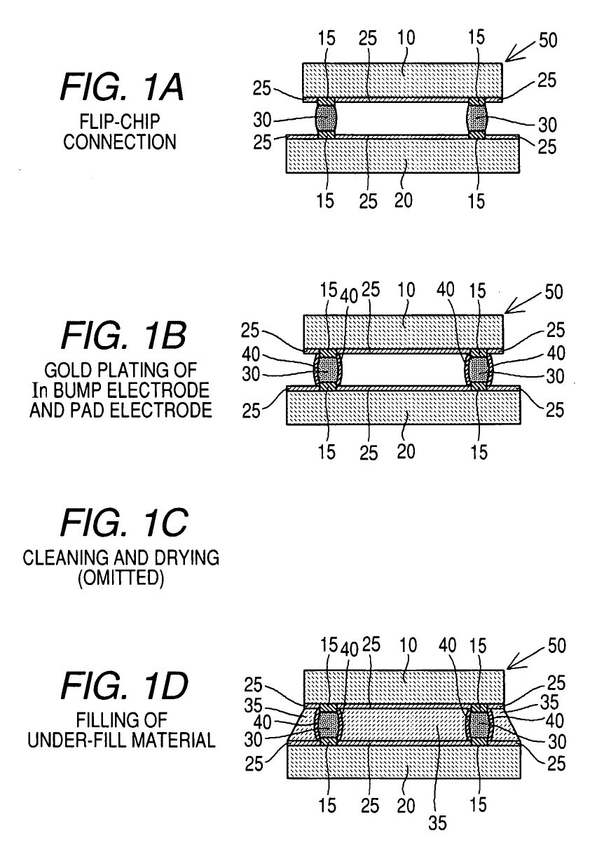

FIGS. 1A to 1D are sectional views for explaining a semiconductor device 50 formed by bonding substrates 10 and 20 via In bump electrodes 30 according to this embodiment. FIG. 1A is a diagram showing flip-chip connection of the substrates, FIG. 1B is a diagram showing gold plating of surfaces of the In bump electrodes 30 and pad electrodes 15, and FIG. 1C is a diagram showing filling of an under-fill material 35.

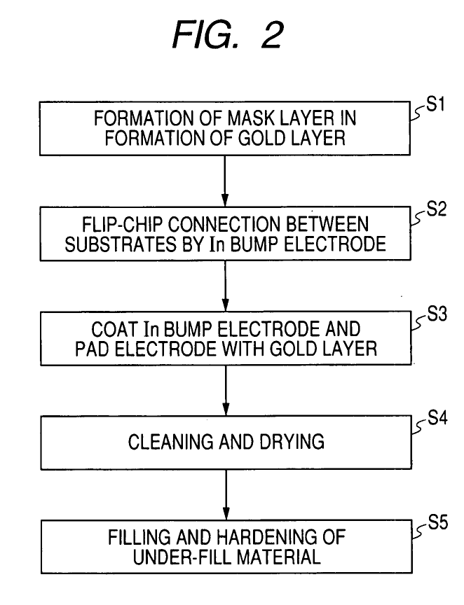

FIG. 2 is a flowchart for explaining a procedure of the bonding of the substrates 10 and 20 via the In bump electrode 30 in the semiconductor device 50.

The In bump electrodes 30 are formed on the pad electrodes 15 of the upper substrate 10 or the lower substrate 10. The upper substrate 10 and the lower substrate 20 are flip-chip connected. In this embodiment, it is assumed that the In bump electrodes 30 are formed on the pad electrodes 15 of the upper substrate 10.

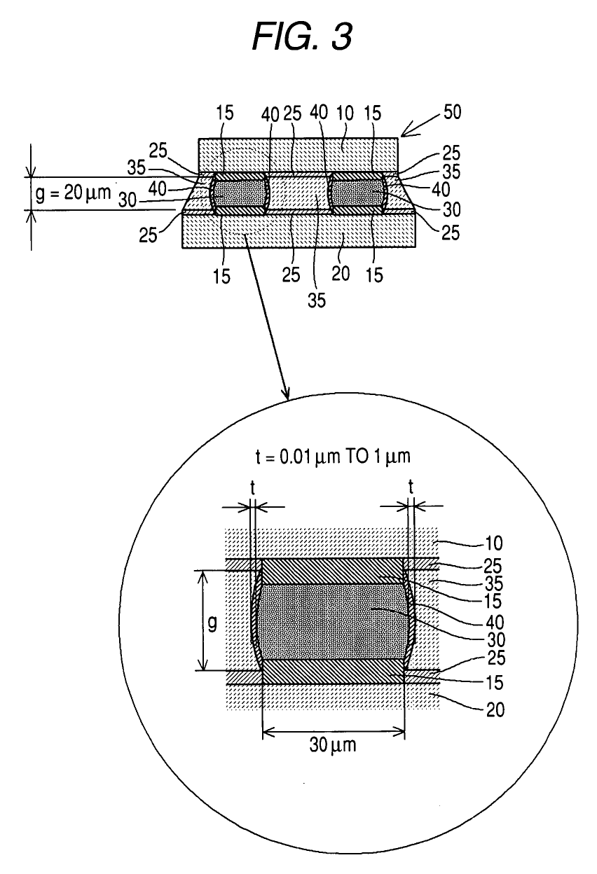

Prior to this flip-chip connection, as indicated by step S1 in FIG. 2, a mask layer (not shown in FIGS. 1A to 1D and FIG. 3) in the formation of gold plating layers 40 is formed. This mask layer is formed on a surface excluding the In bump electrodes 30 and the pad electrodes 15, which are formed on the upper substrate 10, by a resist layer having a thickness of about 1 μm. The mask layer is also formed on a surface excluding the pad electrodes 15, which are formed on the lower substrate 20, by a resist layer having a thickness of about 1 μm. This resist layer is formed using a material easily removable by an organic solvent. After the upper substrate 10 and the lower substrate 20 are flip-chip connected, the resist layer is removed by the organic solvent.

As indicated by step S2 in FIG. 2, the upper substrate 10 is electrically connected to the lower substrate 20 via the In bump electrodes 30 by the flip-chip connection as shown in FIG. 1A.

In the example shown in FIGS. 1A to 1D, the upper substrate 10 is a semiconductor chip substrate having the In bump electrodes 30 formed on the pad electrodes 15 thereof. The lower substrate 20 is a semiconductor chip substrate having the pad electrodes 15 formed thereon. The pad electrodes 15 formed on the upper substrate 10 and the lower substrate 20 are electrically connected by the flip-chip connection. It is also possible to provide a mounting substrate instead of the semiconductor chip substrate of the lower substrate 20.

An external shape of the In bump electrodes 30 formed on the pad electrodes 15 of the upper substrate 10 may be an arbitrary shape such as a circular crown shape or a columnar shape. The In bump electrodes 30 may be connected to the pad electrodes 15, which are formed on the upper substrate 10, via an under-bump electrode metal layer.

Positioning of the In bump electrodes 30 formed on the pad electrodes 15 electrically isolated from each other by an insulating layer 25 and formed on the upper substrate 10 and the pad electrodes 15 formed on the lower substrate 20 is performed. Heating control and load control for the upper substrate 10 and the lower substrate 20 are performed. Consequently, the upper substrate 10 and the lower substrate 20 are connected with a desired gap (e.g., 20 μm to 50 μm) held between the upper substrate 10 and the lower substrate 20.

As described above, after the upper substrate 10 and the lower substrate 20 are flip-chip connected, the resist layer is removed by the organic solvent.

When necessary, step S4 described later is executed to clean the inside of the gap between the upper substrate 10 and the lower substrate 20.

Prior to the filling of the under-fill material 35 in the gap between the upper substrate 10 and the lower substrate 20, as indicated by step S3 in FIG. 2, gold plating is applied to the surfaces of the In bump electrodes 30 and the pad electrodes 15. In other words, the gold plating layers 40 are formed on exposed surfaces (surfaces not bonded with the pad electrodes 15) of the In bump electrodes 30 and exposed surfaces (surfaces not bonded with the In bump electrodes 30) of the pad electrodes 15 (see FIG. 1B).

The gold plating layers 40 are formed by displacement plating for forming films of gold on surfaces using a chemical displacement reaction between metals or chemical reduction plating for depositing gold on surfaces to form films thereon using a chemical reduction reaction between metals.

Electroless plating is performed by immersing the upper substrate 10 and the lower substrate 20 flip-chip connected in, for example, an Au displacement plating liquid. The thickness of the gold plating layers 40 formed on sides (outer peripheral surfaces) of the In bump electrodes 30 is 0.01 μm to 1 μm, for example, 0.05 μm. When the gold plating layers 40 is too thin, performance for protecting the In bump electrodes 30 as the purpose of forming the gold plating layer 40 is insufficient. On the other hand, when the gold plating layers 40 is too thick, the formation of the plating layer takes time and cost increases.

As shown in FIG. 1B, the gold plating layers 40 are formed on surfaces of metal portions, i.e., surfaces of the In bump electrodes 30 and the pad electrodes 15 by plating. The surfaces of the In bump electrodes 30 and the pad electrodes 15 are coated with the gold plating surfaces 40 and the In bump electrodes 30 are shielded from moisture and protected against moisture.

Besides the Au plating, metal plating layers having a melting point higher than that of indium may be formed. For example, layers of metal more excellent in humidity resistance than In such as Sn or Ni may be formed by electroless plating to cover the In bump electrodes 30 and the pad electrodes 15.

The gap between the upper substrate 10 and the lower substrate 20 is cleaned by cleaning (pure water is used) and drying shown in FIG. 1C and indicated by step S4 in FIG. 2. The gap between the upper substrate 10 and the lower substrate 20 is cleaned by a water jet method of feeding a forced flow of water to the gap and cleaning the gap or an ultra-oscillation method of feeding a forced flow of water to the gap with low frequency oscillation to clean the gap.

When step S1 described above is omitted, in forming the gold plating layers 40 on the In bump electrodes 30, the gold plating layers 40 may adhere to the surface of the insulating layer 25. Since strength of the adhesion of the gold plating layers 40 to the insulating layer 25 is not large, in the cleaning, the gold plating layers 40 adhering to the insulating layer 25 are peeled off and washed away and the insulating layer 25 is cleaned.

As shown in FIG. 1D and indicated by step S5 in FIG. 2, in order to protect the junctions of the upper substrate 10 and the lower substrate 20 in a bonded product via the In bump electrodes 30 and securing reliability of the bonded product, the under-fill material 35 is filled in the gap between the upper substrate 10 and the lower substrate 20 as a sealing material and hardened.

It is possible to realize a structure in which the In bump electrodes 30 and the under-fill material 35 do not directly come into contact with each other as shown in FIG. 1D by injecting the under-fill material 35 in the gap between the upper substrate 10 and the lower substrate 20 in a connected component having a connection structure in which the In bump electrodes 30 and the pad electrodes 15 are coated with the gold playing layers 40.

As a result, the gold plating layers 40 that coat the surfaces of the In bump electrodes 30 and the pad electrodes 15 are covered by the under-fill material 35. Thus, the surfaces of the In bump electrodes 30 and the pad electrodes 15 do not directly come into contact with the under-fill material 35 and are not exposed to moisture and it is possible to control an influence of the moisture on the In bump electrodes 30. Therefore, since the In bump electrodes 30 are not rusted by the moisture, it is possible to improve reliability of a bonded product of the substrates via the In bump electrodes 30 and improve reliability of a semiconductor device in which the bonded product is used.

According to this embodiment, it is possible to realize flip-chip mounting performed by using the In bump electrodes that can improve humidity resistance to be as high as that of leadless solder such as Sn—Ag solder and Sn solder.

As described above, step S1 may be omitted. It goes without saying that the gold plating layers 40 can be formed by electrolytic plating.

When the semiconductor device is arranged in a hermetically sealed space in which a neutral as atmosphere in a dry state is filled, it is also possible to omit the filling of the under-fill material in the gap without executing step S5.

FIG. 3 is a sectional view including an enlargement of the junction for explaining an example of dimensions of the junction of the semiconductor device formed by bonding the substrates 10 and 20 via the In bump electrodes 30.

FIG. 3 shows a section and an enlarged section of the junction in a state in which the electrical connection of the upper substrate 10 and the lower substrate 20 via the In bump electrodes 30, the formation of the gold plating layers 40 on the exposed surfaces of the pad electrodes 15 and the In bump electrodes 30, and the filling of the under-fill material 35 in the gap between the upper substrate 10 and the lower substrate 20 are performed.

In FIG. 3, “g” indicates the gap between the upper substrate 10 and the lower substrate 20 bonded and “t” indicates the thickness of the gold plating layers 40. The gold plating layers 40 are formed on the sides (the outer peripheral surfaces) of the pad electrodes 15 and the In bump electrodes 30, which are exposed in a space of the gap “g”, after the upper substrate 10 and the lower substrate 20 are electrically connected via the pad electrodes 15 and before the under-fill material 35 is filled in the gap.

In the example shown in FIG. 3, a state of bonding of the upper substrate 10 and the lower substrate 20 by the flip-chip connection is shown. On the upper substrate 10, the In bump electrode that has a spherical crown having a bottom with a radius of 15 μm and a height of 23 μm as an external shape thereof is formed on the circular pad electrode 15 with a radius of 15 μm. On the lower substrate 20, the circular pad electrode 15 with a radius of 15 μm is formed. Here, g=13 μm and t=0.05 μm.

In the above explanation, the example of forming the Au plating layers on the sides of the In bump electrodes is explained. However, it is sufficient that bump electrodes are formed of an elemental metal having a low melting point and protective layers are formed of metal having a high melting point. For example, in order to form rust preventing layers, plating layers may be formed of rare metal other than Au instead of the Au plating layer.

In the above explanation, the In bump electrodes 30 are formed on the pad electrodes 15 of the upper substrate 10. However, it is also possible to omit step S3 by, after forming an external shape of the In bump electrodes 30 in a circular crown shape, forming the gold plating layers 40 on the outer surfaces of the pad electrodes 15 and the In bump electrodes 30 exposed, selectively etching the gold plating layers 40 near vertexes of the circular crown shapes of the In bump electrodes 30 to leave the gold plating layers 40 in portions at the same height as the gap “g” shown in FIG. 3 from the surface of the insulating layer 25 of the upper substrate 10, and exposing the portions near the vertexes of the In bump electrodes 30 to make it possible to bond the upper substrate 10 and the lower substrate 20.

The embodiment of the present invention has been explained. However, the present invention is not limited to the embodiment and various modifications based on the technical idea of the present invention are possible.

As explained above, the present invention is suitable for an electronic device that needs to be manufactured in a low-temperature process and it is possible to provide a semiconductor device in which deterioration in characteristics of bump electrodes is prevented to improve reliability.

It should be understood by those skilled in the art that various modifications, combinations, sub-combinations, and alterations may occur depending on design requirements and other factors insofar as they are within the scope of the appended claims or the equivalents thereof.

What is claimed is:

1. An electronic device comprising:
bump electrodes that are formed of an elemental metal having a low melting point and electrically bond a first component and a second component; and
protective layers that are formed at least on sides of the bump electrodes and prevent penetration of a substance that deteriorates a characteristic of the bump electrodes.

2. An electronic device according to claim 1, wherein pad electrodes formed on the first and second components, respectively, are electrically connected by the bump electrodes and the protective layers are formed to prevent the bump electrodes from being exposed to the outside.

3. An electronic device according to claim 2, wherein the protective layers are formed on the sides of the bump electrodes.

4. An electronic device according to claim 2, wherein a part of the pad electrodes are coated with the protective layers.

5. An electronic device according to claim 1, wherein the bump electrodes are formed of elemental indium metal.

6. An electronic device according to claim 1, wherein the protective layers are formed of metal having a high melting point.

7. An electronic device according to claim 1, wherein an under-fill material is filled in the gap between the first component and the second component.

8. An electronic device according to claim 1, wherein the first component is a first semiconductor chip and the second component is a second semiconductor chip or amounting substrate.

9. An electronic device according to claim 8, wherein the mounting substrate is an interposer substrate or a motherboard substrate.

10. An electronic device according to claim 1, wherein the electronic device constitutes a semiconductor device.

11. A method of manufacturing an electronic device comprising the steps of:
electrically bonding a first component and a second component using bump electrodes formed of an elemental metal having a low melting point; and
forming, at least on sides of the bump electrodes, protective layers that prevent penetration of a substance that deteriorates a characteristic of the bump electrodes.

12. A method of manufacturing an electronic device according to claim 11, further comprising the step of filling an under-fill material in a gap between the first component and the second component.

13. A method of manufacturing an electronic device according to claim 11, wherein, in the step of forming protective layers, plating layers of metal having a high melting point are formed as the protective layers.

14. A method of manufacturing an electronic device according to claim 13, wherein the plating layers are formed by electroless plating.
